(19) United States
(12) Patent Application Publication
(10) Pub. No.: US 2018/0172365 A1
(43) Pub. Date: Jun. 21, 2018

(54) LIQUID COOLING SYSTEM

(71) Applicant: COOLER MASTER CO., LTD., New Taipei City (TW)

(72) Inventors: Chang-Han Tsai, New Taipei City (TW); Shui-Fa Tsai, New Taipei City (TW); Hsin-Hung Chen, New Taipei City (TW)

(21) Appl. No.: 15/675,785

(22) Filed: Aug. 13, 2017

(30) Foreign Application Priority Data
Dec. 19, 2016 (TW) 105142026

(51) Int. Cl. F28F 9/26; F28D 15/00; H05K 7/20

(52) U.S. Cl. CPC F28F 9/262; F28F 2280/10; H05K 7/20263; F28D 15/00

(57) ABSTRACT

A liquid cooling system includes a liquid cooling head, a radiator, a first support member and a second support member. The liquid cooling head has at least one first outlet and at least one first inlet. The radiator has a second outlet and a second inlet. The first support member has at least one first end portion connected to the first outlet, a second end portion pivotally connected to the second inlet, and at least one first passage. The second support member has at least one third end portion connected to the first inlet, a fourth end portion pivotally connected to the second outlet, and at least one second passage. The first and second support members support the radiator and the radiator is capable of rotating with respect to the liquid cooling head by the second and fourth end portions.

### BACKGROUND OF THE INVENTION

### 1. Field of the Invention

The invention relates to a liquid cooling system and, more particularly, to a liquid cooling system allowing a radiator to rotate with respect to a liquid cooling head.

### 2. Description of the Prior Art

Heat dissipating device is a significant component for electronic devices. When an electronic device is operating, the current in circuit will generate unnecessary heat due to impedance. If the heat is accumulated in the electronic components of the electronic device without dissipating immediately, the electronic components may get damage due to the accumulated heat. Therefore, the performance of heat dissipating device is a significant issue for the electronic device.

So far the heat dissipating device used in the electronic device usually consists of a heat pipe, a heat dissipating fin and a fan, wherein an end of the heat pipe contacts the electronic component, which generates heat during operation, another end of the heat pipe is connected to the heat dissipating fin, and the fan blows air to the heat dissipating fin, so as to dissipate heat. However, the fan may generate noise and consume high power under high speed and the aforesaid problems are difficult to be solved by the manufacturer. Accordingly, a liquid cooling system is developed.

In general, a liquid cooling system essentially consists of a liquid cooling head, a radiator and a pump. When the liquid cooling system is dissipating heat from an electronic component, the pump transports a cooling liquid to the liquid cooling head, the cooling liquid absorbs the heat generated by the electronic component, and then the radiator cools the cooling liquid. In the liquid cooling system, the related positions between the liquid cooling head, the radiator and the pump are fixed and cannot be adjusted. Furthermore, since the arrangements of the electronic components in different electronic devices are different from each other, the space used for installing the liquid cooling system in the electronic device is limited. Accordingly, the liquid cooling system has to be customized for different electronic devices, such that the liquid cooling system is not flexible in use and the manufacturing cost may increase.

### SUMMARY OF THE INVENTION

The invention provides a liquid cooling system allowing a radiator to rotate with respect to a liquid cooling head, so as to solve the aforesaid problems.

According to an embodiment of the invention, a liquid cooling system comprises a liquid cooling head, a radiator, a first support member and a second support member. The liquid cooling head has at least one first outlet and at least one first inlet. The radiator has a second outlet and a second inlet. The first support member has at least one first end portion, a second end portion and at least one first passage. The first end portion is connected to the first outlet and the second end portion is pivotally connected to the second inlet, such that the first passage communicates with the first outlet and the second inlet. The second support member has at least one third end portion, a fourth end portion and at least one second passage. The third end portion is connected to the first inlet and the fourth end portion is pivotally connected to the second outlet, such that the second passage communicates with the first inlet and the second outlet. The first support member and the second support member support the radiator and the radiator is capable of rotating with respect to the liquid cooling head by the second end portion and the fourth end portion.

According to another embodiment of the invention, a liquid cooling system comprises a liquid cooling head, a radiator, a first support member and a second support member. The liquid cooling head has a plurality of first outlets and a plurality of first inlets. The radiator has a second outlet and a second inlet. The radiator is disposed above the liquid cooling head. The first support member has a first end portion and a second end portion. The first end portion is disposed at the first outlets and the second end portion is disposed at the second inlet. The second support member has a third end portion and a fourth end portion. The third end portion is disposed at the first inlets and the fourth end portion is disposed at the second outlet. The liquid cooling head, the radiator, the first support member and the second support member form a circulation path for a liquid flowing therein.

As mentioned in the above, the invention uses two support members to support the radiator and disposes the passages in the support members to communicate with the liquid cooling head and the radiator, such that the passages of the support members, the liquid cooling head and the radiator form a circulation path for a liquid (e.g. cooling liquid) flowing therein. Furthermore, since the radiator can rotate with respect to the liquid cooling head by the end portions of the support members, a user or a manufacturer can adjust the position of the radiator with respect to the liquid cooling head according to the arrangement of electronic components in an electronic device, so as to prevent the liquid cooling system from interfering with the electronic components in the electronic device. Accordingly, the liquid cooling system of the invention can be applied to various electronic devices.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic view illustrating a liquid cooling system according to an embodiment of the invention.

FIG. 2 is an exploded view illustrating the liquid cooling system shown in FIG. 1.

FIG. 3 is an exploded view illustrating the liquid cooling system shown in FIG. 1 from another viewing angle.

FIG. 4 is an exploded view illustrating the liquid cooling head shown in FIG. 1.

FIG. 5 is a schematic view illustrating the radiator shown in FIG. 1 after being rotated.

FIG. 6 is a schematic view illustrating a liquid cooling system according to another embodiment of the invention.

FIG. 7 is an exploded view illustrating the liquid cooling system shown in FIG. 6.

FIG. 8 is an exploded view illustrating the liquid cooling system shown in FIG. 6 from another viewing angle.

FIG. 9 is a schematic view illustrating the radiator shown in FIG. 6 after being rotated.

### DETAILED DESCRIPTION

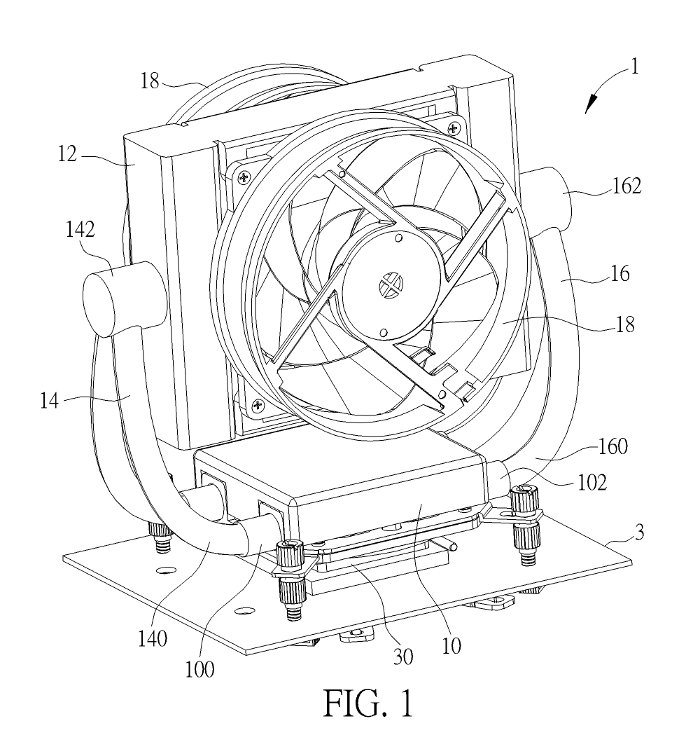

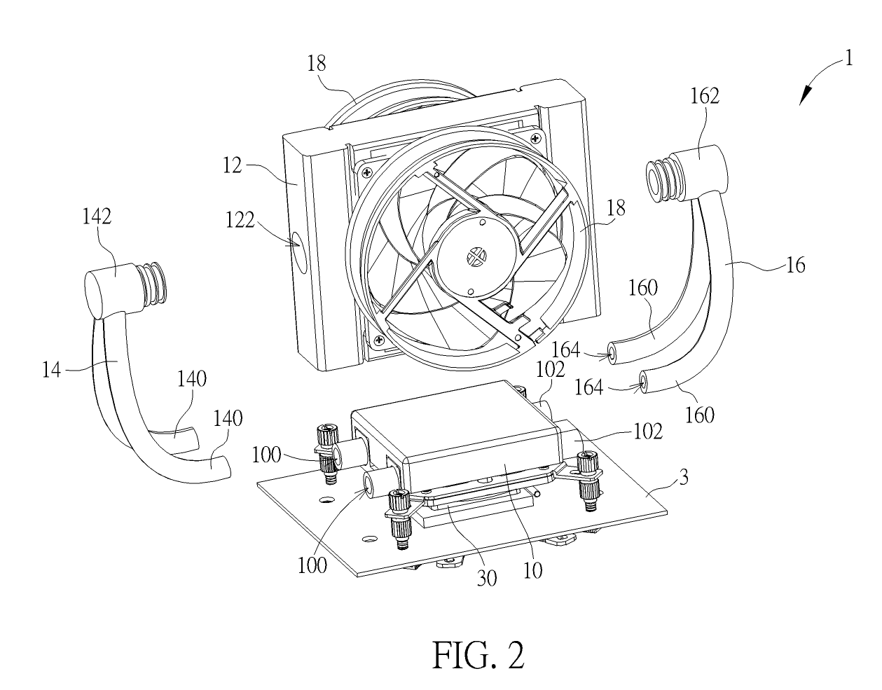

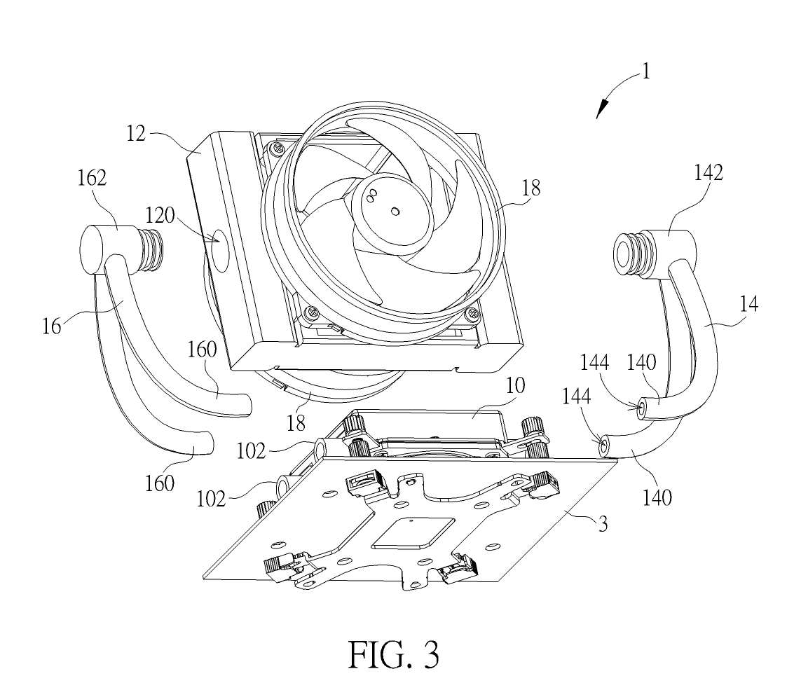

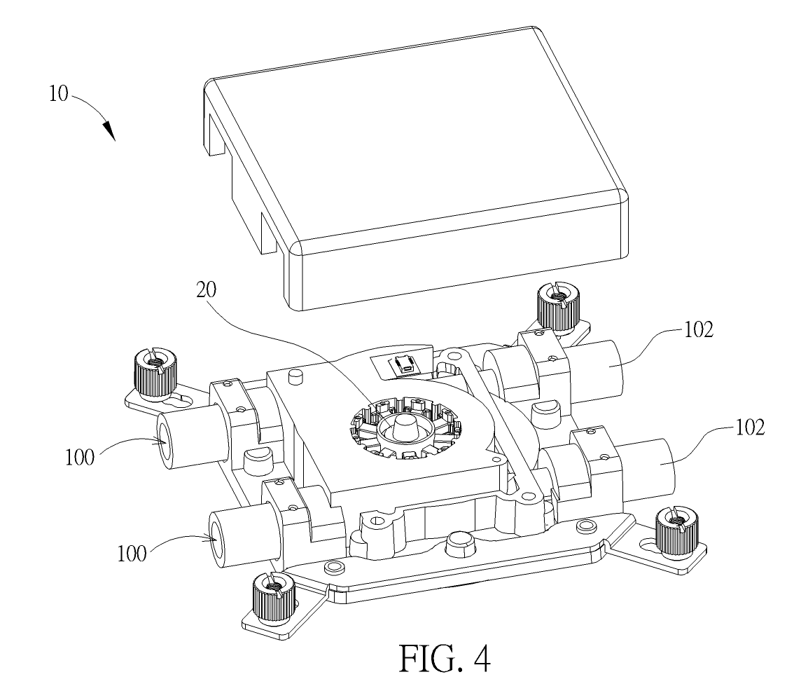

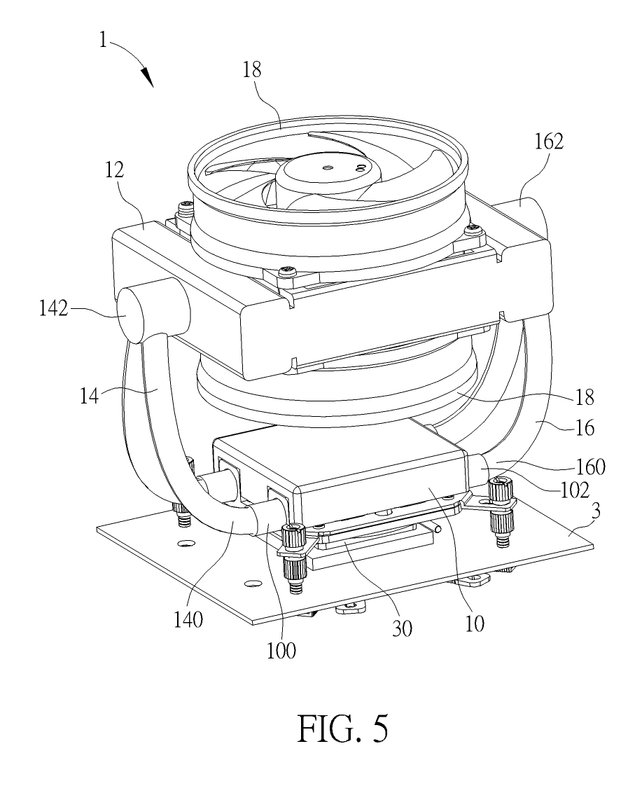

Referring to FIGS. 1 to 5, FIG. 1 is a schematic view illustrating a liquid cooling system 1 according to an embodiment of the invention, FIG. 2 is an exploded view illustrating the liquid cooling system 1 shown in FIG. 1, FIG. 3 is an exploded view illustrating the liquid cooling system 1 shown in FIG. 1 from another viewing angle, FIG. 4 is an exploded view illustrating the liquid cooling head 10 shown in FIG. 1, and FIG. 5 is a schematic view illustrating the radiator 12 shown in FIG. 1 after being rotated.

As shown in FIGS. 1 to 3, the liquid cooling system. 1 comprises a liquid cooling head 10, a radiator 12, a first support member 14, a second support member 16 and at least one fan 18. The fan 10 is disposed on the radiator 12. In this embodiment, the liquid cooling system 1 comprises two fans 18, wherein the two fans 18 are disposed on opposite sides of the radiator 12, respectively. However, in another embodiment, the liquid cooling system 1 may comprise one single fan 18. In other words, the number of the fans 18 can be determined according to practical applications.

The liquid cooling head 10 has at least one first outlet 100 and at least one first inlet 102. In this embodiment, the liquid cooling head 10 has two first outlets 100 and two first inlets 102. However, in another embodiment, the liquid cooling head 10 may have one single first outlet 100 and one single first inlet 102. Furthermore, in another embodiment, the liquid cooling head 10 may have more than two first outlets 100 and more than two first inlets 102. In other words, the number of the first outlets 100 and the first inlets 102 can be determined according to practical applications.

The radiator 12 is disposed above the liquid cooling head 10. The radiator 12 has a second outlet 120 and a second inlet 122. The first support member 14 has at least one first end portion 140, a second end portion 142 and at least one first passage 144. In this embodiment, the first support member 14 has two first end portions 140 and two first passages 144, wherein the number of the first end portions 140 and the first passages 144 is corresponding to the number of the first outlets 100 of the liquid cooling head 10. Furthermore, the two first passages 144 communicate with each other in the second end portion 142. The first end portions 140 of the first support member 14 are connected to the first outlets 100 of the liquid cooling head 10 and the second end portion 142 of the first support member is pivotally connected to the second inlet 122 of the radiator 12, such that the first passages 144 of the first support member 14 communicate with the first outlets 100 of the liquid cooling head 10 and the second inlet 122 of the radiator 12. In other words, the first end portions 140 of the first support member 14 are disposed at the first outlets 100 of the liquid cooling head 10 and the second end portion 142 of the first support member 14 is disposed at the second inlet 122 of the radiator 12.

The second support member 16 has at least one third end portion 160, a fourth end portion 162 and at least one second passage 164. In this embodiment, the second support member 16 has two third end portions 160 and two second passages 164, wherein the number of the third end portions 160 and the second passages 164 is corresponding to the number of the first inlets 102 of the liquid cooling head 10. Furthermore, the two second passages 164 communicate with each other in the fourth end portion 162. The third end portions 160 of the second support member 16 are connected to the first inlets 102 of the liquid cooling head 10 and the fourth end portion 162 of the second support member 16 is pivotally connected to the second outlet 120 of the radiator 12, such that the second passages 164 of the second support member 16 communicate with the first inlets 102 of the liquid cooling head 10 and the second outlet 120 of the radiator 12. In other words, the third end portions 160 of the second support member are disposed at the first inlets 102 of the liquid cooling head 10 and the fourth end portion 162 of the second support member 16 is disposed at the second outlet 120 of the radiator 12.

Accordingly, the first passages 144 of the first support member 14, the second passages 164 of the second support member 16, the liquid cooling head 10 and the radiator 12 can form a circulation path for a liquid (e.g. cooling liquid) flowing therein.

In this embodiment, the first support member 14 and the second support member 16 may be made of metal (e.g. copper, aluminum, stainless steel, etc.) or plastic according to practical applications. Furthermore, the first support member 14 and the second support member 16 may be, but not limited to, tubular. In another embodiment, the first support member 14 and the second support member 16 may be rectangular or other shapes.

As shown in FIG. 1, the first support member 14 and the second support member 16 support the radiator 12, such that the radiator 12 is located above the liquid cooling head 10. Since the two first end portions 140 of the first support member 14 are connected to the two first outlets 100 of the liquid cooling head 10 and the two third end portions 160 of the second support member 16 are connected to the two first inlets 102 of the liquid cooling head 10, the first support member 14 and the second support member 16 can support the radiator 12 above the liquid cooling head 10 more stably.

Still further, since the second end portion 142 of the first support member 14 is pivotally connected to the second inlet 122 of the radiator 12 and the fourth end portion 162 of the second support member 16 is pivotally connected to the second outlet 120 of the radiator 12, the radiator 12 is capable of rotating with respect to the liquid cooling head 10 by the second end portion 142 of the first support member 14 and the fourth end portion 162 of the second support member 16. For example, a user may rotate the radiator 12 with respect to the liquid cooling head 10 between a vertical position shown in FIG. 1 and a horizontal position shown in FIG. 5. Accordingly, the user or a manufacturer can adjust the position of the radiator 12 with respect to the liquid cooling head 10 according to the arrangement of electronic components in an electronic device, so as to prevent the liquid cooling system 1 from interfering with the electronic components in the electronic device. Accordingly, the liquid cooling system 1 of the invention can be applied to various electronic devices.

In this embodiment, the liquid cooling head 10 may comprise a pump 20, as shown in FIG. 4. In practical applications, the liquid cooling system 1 may be disposed on a circuit board 3, such that the liquid cooling head 10 may be attached on an electronic component 30 of the circuit board 3, e.g. a processor, a graphics card, other integrated circuit chips and so on. When the liquid cooling system 1 is dissipating heat from the electronic component 30, the liquid cooling head 10 absorbs the heat generated by the electronic component 30 and then a cooling liquid (not shown) in the liquid cooling head 10 absorbs the heat. Then, the pump 20 transports the cooling liquid out of the liquid cooling head 10 from the first outlets 100, such that the cooling liquid flows back to the liquid cooling head 10 from the first inlets 102 through the first passages 144 of the first support member 14, the radiator 12 and the second passages 164 of the second support member 16. When the cooling liquid flows through the radiator 12, the fan 18 can dissipate heat from the radiator 12, so as to cool the cooling liquid.

It should be noted that the pump 20 may also be disposed outside the liquid cooling head 10, so the pump 20 is not limited to be disposed in the liquid cooling head 10.

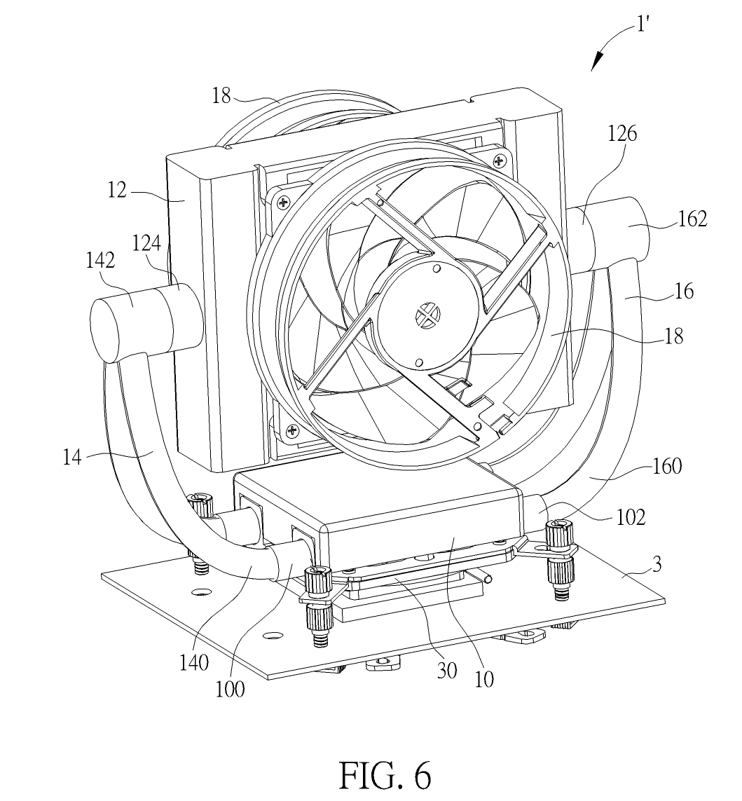

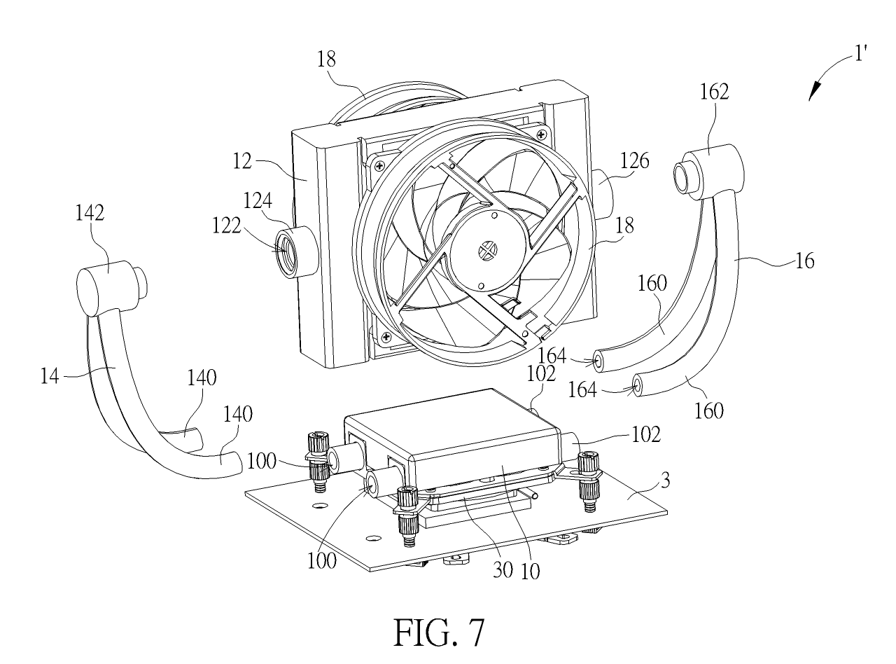

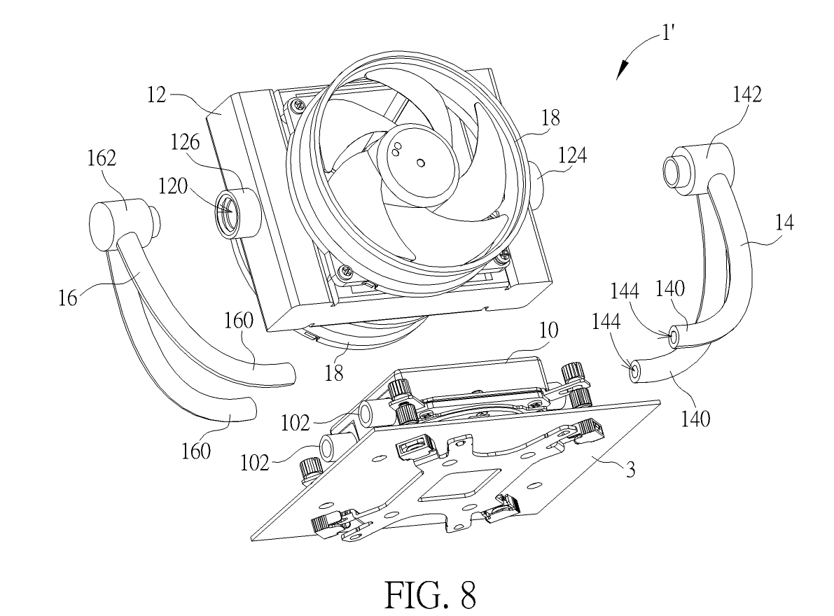

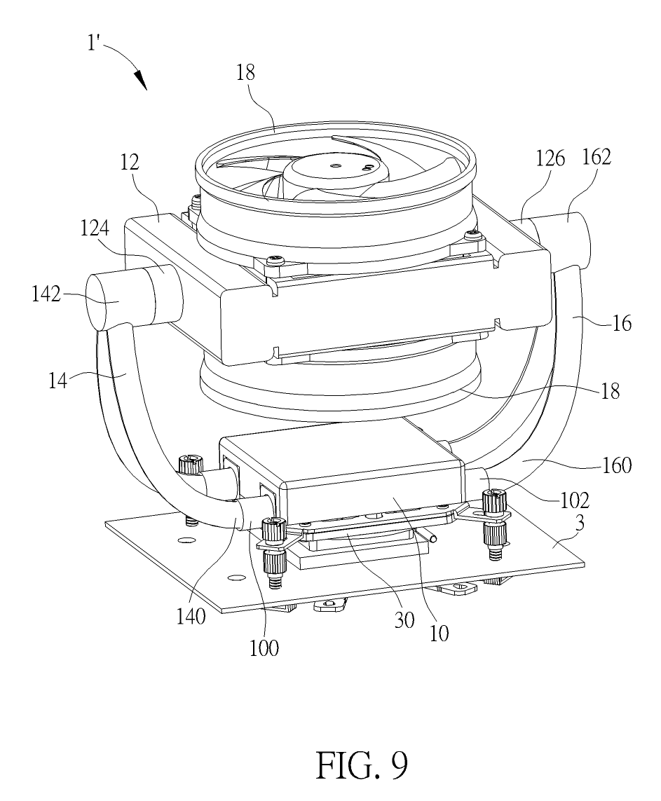

Referring to FIGS. 6 to 9, FIG. 6 is a schematic view illustrating a liquid cooling system 1′ according to another embodiment of the invention, FIG. 7 is an exploded view illustrating the liquid cooling system 1′ shown in FIG. 6, FIG. 8 is an exploded view illustrating the liquid cooling system 1′ shown in FIG. 6 from another viewing angle, and FIG. 9 is a schematic view illustrating the radiator 12 shown in FIG. 6 after being rotated.

The main difference between the liquid cooling system 1′ and the aforesaid liquid cooling system 1 is that the radiator 12 of the liquid cooling system 1′ comprises a first pivot axle 124 and a second pivot axle 126, as shown in FIGS. 6 to 9. In this embodiment, the second inlet 122 of the radiator 12 may be formed on the first pivot axle 124 and the second outlet 120 of the radiator 12 may be formed on the second pivot axle 126. Accordingly, the second end portion 142 of the first support member 14 may be pivotally connected to the first pivot axle 124 of the radiator 12 and the fourth end portion 162 of the second support member 16 may be pivotally connected to the second pivot axle 126 of the radiator 12.

Since the second end portion 142 of the first support member 14 is pivotally connected to the first pivot axle 124 of the radiator 12 and the fourth end portion 162 of the second support member 16 is pivotally connected to the second pivot axle 126 of the radiator 12, the radiator 12 is capable of rotating with respect to the liquid cooling head 10 by the second end portion 142 of the first support member 14 and the fourth end portion 162 of the second support member 16. For example, a user may rotate the radiator 12 with respect to the liquid cooling head 10 between a vertical position shown in FIG. 6 and a horizontal position shown in FIG. 9. Accordingly, the user or a manufacturer can adjust the position of the radiator 12 with respect to the liquid cooling head 10 according to the arrangement of electronic components in an electronic device, so as to prevent the liquid cooling system 1 from interfering with the electronic components in the electronic device. Accordingly, the liquid cooling system 1 of the invention can be applied to various electronic devices.

It should be noted that the same elements in FIGS. 6-9 and FIGS. 1-5 are represented by the same numerals, so the repeated explanation will not be depicted herein again.

As mentioned in the above, the invention uses two support members to support the radiator and disposes the passages in the support members to communicate with the liquid cooling head and the radiator, such that the passages of the support members, the liquid cooling head and the radiator form a circulation path for a liquid (e.g. cooling liquid) flowing therein. Furthermore, since the radiator can rotate with respect to the liquid cooling head by the end portions of the support members, a user or a manufacturer can adjust the position of the radiator with respect to the liquid cooling head according to the arrangement of electronic components in an electronic device, so as to prevent the liquid cooling system from interfering with the electronic components in the electronic device. Accordingly, the liquid cooling system of the invention can be applied to various electronic devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A liquid cooling system comprising:
a liquid cooling head having at least one first outlet and at least one first inlet;
a radiator having a second outlet and a second inlet;
a first support member having at least one first end portion, a second end portion and at least one first passage, the first end portion being connected to the first outlet, the second end portion being pivotally connected to the second inlet, such that the first passage communicates with the first outlet and the second inlet; and
a second support member having at least one third end portion, a fourth end portion and at least one second passage, the third end portion being connected to the first inlet, the fourth end portion being pivotally connected to the second outlet, such that the second passage communicates with the first inlet and the second outlet;
wherein the first support member and the second support member support the radiator and the radiator is capable of rotating with respect to the liquid cooling head by the second end portion and the fourth end portion.

2. The liquid cooling system of claim 1, wherein the radiator comprises a first pivot axle and a second pivot axle, the second inlet is formed on the first pivot axle, and the second outlet is formed on the second pivot axle.

3. The liquid cooling system of claim 1, wherein the first support member and the second support member are made of metal or plastic.

4. The liquid cooling system of claim 1, wherein the first support member and the second support member are tubular.

5. The liquid cooling system of claim 1, wherein the liquid cooling head comprises a pump.
